(19) United States
(12) Patent Application Publication
(10) Pub. No.: US 2014/0184367 A1
(43) Pub. Date: Jul. 3, 2014

(54) WATERPROOF ELECTRONIC DEVICE AND ITS MAGNETIC SENSING SWITCH

(71) Applicant: HON HAI PRECISION INDUSTRY CO., LTD., New Taipei (TW)

(72) Inventor: KUANG-YAO LIAO, New Taipei (TW)

(73) Assignee: HON HAI PRECISION INDUSTRY CO., LTD., New Taipei (TW)

(21) Appl. No.: 14/092,950

(22) Filed: Nov. 28, 2013

(30) Foreign Application Priority Data
Dec. 27, 2012 (TW) 101150533

(51) Int. Cl. H03K 17/95

(52) U.S. Cl. CPC H03K 17/95
USPC 335/205

(57) ABSTRACT

A waterproof electronic device includes a shell, a magnetic sensing switch, and a button responding circuit arranged in the interior. The magnetic sensing switch includes a magnetic sensing unit arranged in the interior of the shell and a magnetic button arranged on the exterior of the shell. The magnetic sensing unit is coupled to the button responding circuit. When the magnetic button is pushed closer to the magnetic sensing unit by a predetermined distance, the magnetic sensing unit is activated by the Hall effect, and outputs a trigger signal to the button responding circuit, and the button responding circuit performs a desired function.

### BACKGROUND

1. Technical Field

The present disclosure relates to switches, particular to a waterproof electronic device and its magnetic sensing switch.

2. Description of Related Art

Mechanical switches are widely used. However, most of the mechanical switches are contact switches and have poor waterproof performance. When used in some special environment, such as underwater, these mechanical switches easily break down. Existing Hall switches have good waterproof performance, and have a magnetic element and a Hall sensor to perform their functions. However, external magnetic interference interferes with the switches affect operation.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the present disclosure. Moreover, in the drawings, like reference numerals designate corresponding parts throughout the several views.

FIG. 1 is a schematic diagram of an embodiment of a waterproof electronic device.

FIG. 2 is an embodiment of a schematic circuit diagram of the waterproof electronic device of FIG. 1.

### DETAILED DESCRIPTION

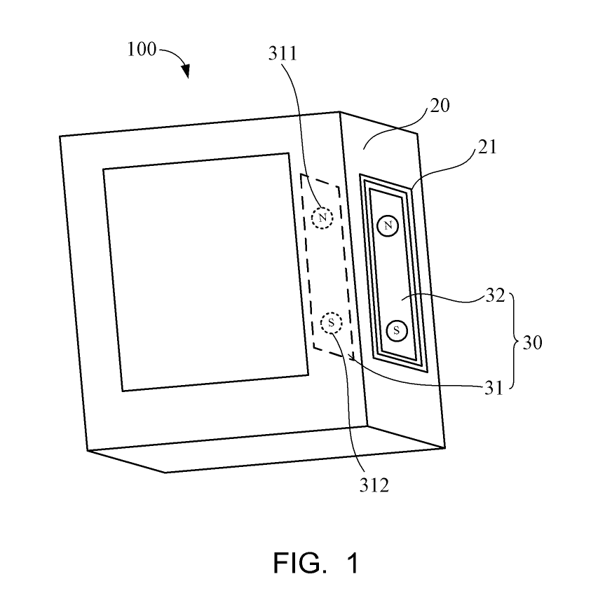

FIG. 1 shows a waterproof electronic device 100 which includes a shell 20 and a magnetic sensing switch 30. The waterproof electronic device 100 can be a smart phone, an electronic wrist watch, or a flashlight.

The magnetic sensing switch 30 includes a magnetic sensing unit 31 arranged in the interior of the shell 20 and a magnetic button 32 arranged on the exterior of the shell 20. In the embodiment, a groove 21 is defined on an external surface of the shell 20 for receiving the magnetic button 32. In the embodiment, the magnetic button 32 is a spring-loaded push button which may be momentary or latching in function. The magnetic button 32 can stay in a first position, move to a second position closer to the interior of the groove 21 when pressed, and return to the first position when it is pushed again or when a pressing force is removed.

In the embodiment, the magnetic sensing unit 31 is a Hall sensor, and includes an N-pole sensor 311 and an S-pole sensor 312. In the embodiment, the magnetic button 32 is a permanent magnet, and has an N-pole and an S-pole at opposite ends. In the embodiment, the N-pole and the S-pole of the magnetic button 32 spatially and respectively correspond to the N-pole sensor 311 and the S-pole sensor 312 of the magnetic sensing unit 31.

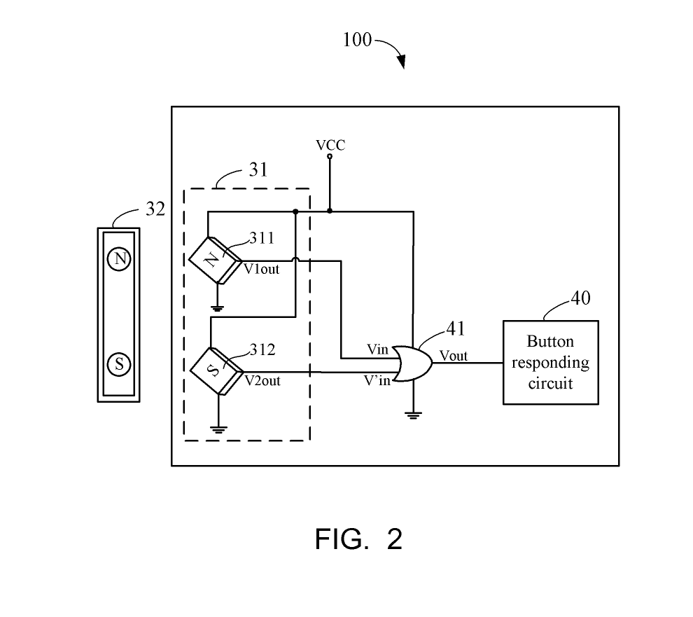

FIG. 2 shows that the waterproof electronic device 100 further includes a button responding circuit 40 arranged in the interior of the shell 20. The magnetic sensing unit 31 is coupled to the button responding circuit 40. When the magnetic button 32 is pushed to the second position, which is closer to the magnetic sensing unit 31 by a predetermined distance, the magnetic sensing unit 31 is activated by the Hall effect, and outputs a trigger signal to the button responding circuit 40. The button responding circuit 40 receives and responds to the trigger signal, and performs a desired function.

In the embodiment, the waterproof electronic device 100 further includes a logic unit 41. The logic unit 41 includes a first input terminal Vin, a second input terminal V′in, and an output terminal Vout. In the embodiment, the first input terminal Vin and the second input terminal V′in are electrically connected respectively to an output terminal V1out of the N-pole sensor 311 and an output terminal V2out of the S-pole sensor 312, and the output terminal Vout of the logic unit 41 is electrically connected to the button responding circuit 40. In other embodiments, the button responding circuit 40 can be a function chip, with one of its function pins connected to the output terminal Vout of the logic unit 41.

In the embodiment, the logic unit 41 is an OR gate, and is configured to execute an OR function in relation to signals output from the N-pole sensor 311 and the S-pole sensor 312, to yield the trigger signal.

In the embodiment, each of the N-pole sensor 311 and the S-pole sensor 312 outputs a logic high voltage signal, such as “1,” if they are not activated, and the logic unit 41 receives logic high voltage signals output from the N-pole sensor 311 and the S-pole sensor 312, and executes an OR function in relation to the logic high voltage signals to yield a logic high voltage signal. If both of the N-pole sensor 311 and the S-pole sensor 312 are activated by the Hall effect, each of sensors 311, 312 outputs a logic low voltage signal, such as “0.” The logic unit 41 receives the logic low voltage signals, and executes an OR function in relation to the logic low voltage signals to yield a logic low voltage signal.

In the embodiment, if only one of the N-pole sensor 311 and the S-pole sensor 312 is activated by the Hall effect, only one of the sensors 311, 312 will output a logic low voltage signal, and the other one of the sensors 311, 312 will output a logic high voltage signal, and the logic unit 41 executes an OR function in relation to the logic low voltage signal and the logic high voltage signal, to yield a logic high voltage signal.

In the embodiment, the button responding circuit 40 is activated by a logic low voltage signal, and performs a desired function when it receives a logic low voltage signal. Therefore, the waterproof electronic device 100 can be used underwater at any depth, and avoids external magnetic interference, and unintended operations.

Moreover, it is to be understood that the disclosure may be embodied in other forms without departing from the spirit thereof. Thus, the present examples and embodiments are to be considered in all respects as illustrative and not restrictive, and the disclosure is not to be limited to the details given herein.

What is claimed is:

1. A waterproof electronic device comprising:
a shell;
a magnetic sensing switch comprising a magnetic sensing unit arranged in the interior of the shell and a magnetic button arranged on the exterior of the shell; and
a button responding circuit arranged in the interior of the shell and coupled to the magnetic sensing unit;
wherein when the magnetic button is pushed closer to the magnetic sensing unit by a predetermined distance, the magnetic sensing unit is activated by the Hall effect, and outputs a trigger signal to the button responding circuit, and the button responding circuit responds to the trigger signal and performs a desired function.

2. The waterproof electronic device as described in claim 1, wherein the magnetic sensing unit comprises an N-pole sensor and an S-pole sensor, the magnetic button is a permanent magnet and has an N-pole and an S-pole at opposite ends, wherein the N-pole and the S-pole of the magnetic button spatially and respectively correspond to the N-pole sensor and the S-pole sensor of the magnetic sensing unit.

3. The waterproof electronic device as described in claim 2, wherein the magnetic sensing unit is a Hall sensor.

4. The waterproof electronic device as described in claim 2, further comprising a logic unit, the logic unit comprising a first input terminal, a second input terminal, and an output terminal, wherein the first input terminal and the second input terminal are electrically connected respectively to an output terminal of the N-pole sensor and an output terminal of the S-pole sensor, and the output terminal of the logic unit is electrically connected to the button responding circuit.

5. The waterproof electronic device as described in claim 4, wherein the logic unit is an OR gate, and is configured to execute an OR function in relation to signals output from the N-pole sensor and the S-pole sensor, to yield the trigger signal.

6. The waterproof electronic device as described in claim 5, wherein each of the N-pole sensor and the S-pole sensor outputs a logic high voltage signal if they are not activated, and the logic unit receives logic high voltage signals output from the N-pole sensor and the S-pole sensor, and executes an OR function in relation to the logic high voltage signals to yield a logic high voltage signal; if both of the N-pole sensor and the S-pole sensor are activated by the Hall effect, each of the sensors outputs a logic low voltage signal; the logic unit receives logic low voltage signals, and executes an OR function in relation to the logic low voltage signals to yield a logic low voltage signal.

7. The waterproof electronic device as described in claim 6, wherein the button responding circuit is activated by a logic low voltage signal, and performs a desired function when it receives a logic low voltage signal.

8. The waterproof electronic device as described in claim 1, wherein the shell defines a groove on an external surface thereof for receiving the magnetic button.

9. The waterproof electronic device as described in claim 8, wherein the magnetic button is a spring-loaded push button which is momentary or latching in function, and stays in a first position, moves to a second position closer to the interior of the groove when pressed, and returns to the first position when it is pushed again or when a pressing force is removed.

10. A magnetic sensing switch used in a waterproof electronic device, the waterproof electronic device comprising a shell and a button responding circuit arranged in the interior of the shell, the magnetic sensing switch comprising a magnetic sensing unit arranged in the interior of the shell and a magnetic button arranged on the exterior of the shell, wherein the magnetic sensing unit is coupled to the button responding circuit, when the magnetic button is pushed closer to the magnetic sensing unit by a predetermined distance, the magnetic sensing unit is activated by the Hall effect, and outputs a trigger signal to the button responding circuit, to make the button responding circuit perform a desired function.

11. The magnetic sensing switch as described in claim 10, wherein the magnetic sensing unit comprises an N-pole sensor and an S-pole sensor, the magnetic button is a permanent magnet and has an N-pole and an S-pole at opposite ends, wherein the N-pole and the S-pole of the magnetic button spatially and respectively correspond to the N-pole sensor and the S-pole sensor of the magnetic sensing unit.

12. The magnetic sensing switch as described in claim 11, wherein the magnetic sensing unit is a Hall sensor.

13. The magnetic sensing switch as described in claim 11, wherein each of the N-pole sensor and the S-pole sensor outputs a logic high voltage signal if they are not activated;
if both the N-pole sensor and the S-pole sensor are activated by the Hall effect, each of the sensors outputs a logic low voltage signal.
